(19) United States
(12) Patent Application Publication
(10) Pub. No.: US 2007/0069386 A1
(43) Pub. Date: Mar. 29, 2007

(54) Memory circuit

(75) Inventor: Mitsuasa Takahashi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC LCD Technologies, Ltd.

(21) Appl. No.: 11/525,932

(22) Filed: Sep. 25, 2006

(30) Foreign Application Priority Data
Sep. 26, 2005 (JP) 2005-277913

(51) Int. Cl. H01L 23/52

(52) U.S. Cl. 257/758

(57) ABSTRACT

A memory circuit includes a first resistor composed of chalcogenide, a second resistor composed of chalcogenide, and electrically connected in series to the first resistor, and an inverter having an input terminal electrically connected to a node through which the first and second resistors are electrically connected to each other.

### BACKGROUND OF THE INVENTION

1. Field of the Invention

The invention relates to a memory circuit.

2. Description of the Related Art

With recent development of technology, there has been suggested a semiconductor device such as a non-volatile memory which makes use of variance in a resistance caused by variance in a phase in a thin film composed of chalcogenide, for instance, in Japanese Patent Application Publication No. 2005-71500.

FIG. 1 is a circuit diagram of a memory circuit 1000 suggested in the above-identified Publication.

With reference to FIG. 1, the memory circuit 1000 is comprised of a resistor 1001 composed of chalcogenide, and having a resistance variable in accordance with phase variation, a bit line (BL) 1002 electrically connected to one end of the resistor 1001, a first switching transistor 1003 having a drain terminal electrically connected to the other end of the resistor 1001, a second switching transistor 1004 having a drain terminal electrically connected to the other end of the resistor 1001, a write-word line (WWL) 1005 electrically connected to a gate terminal of the first switching transistor 1003, a common word line (CWL) 1006 electrically connected to a gate terminal of the second switching transistor 1004, and a power-source line (VSS) 1007 electrically connected to source terminals of the first and second switching transistors 1003 and 1004.

When data is written into the memory circuit 1000, a high-level signal is input into both the common word line (CWL) 1006 and the write-word line (WWL) 1005 in a selected row to thereby turn on the first and second switching transistors 1003 and 1004. Data to be written into the memory circuit 1000 is determined in accordance with a pattern of a data-writing current. Herein, the pattern of a data-writing current includes a level of a current and a period of time during which a data-writing current is input into the memory circuit 1000, for instance.

When data is read out of the memory circuit 1000, only the common word line (CWL) 1006 among the common word line (CWL) 1006 and the write-word line (WWL) 1005 is rendered at a high level to thereby turn on only the second switching transistor 1004 among the first and second switching transistors 1003 and 1004. Thus, data to be read out of the memory circuit 1000, among data stored in the memory circuit 1000, is determined in accordance with a resistance between the bit line (BL) 1002 and the power-source line (VSS) 1007.

In the conventional memory circuit 1000, a resistance is detected in accordance with a high or low data pattern which is measured by means of a sense-amplifier (not illustrated) and a comparator (not illustrated). Accordingly, both of the sense-amplifier and the comparator are necessary to be able to measure a pattern with high accuracy.

The sense-amplifier and the comparator were conventionally comprised of a CMOS circuit fabricated on a mono-crystal silicon substrate.

As is obvious in view of the explanation made above, the conventional memory circuit 1000 had to include a sense-amplifier and a comparator in order to detect a condition thereof, rendering the memory circuit 1000 complex in structure and high in cost.

Furthermore, since a silicon chip has to be attached to a thin film transistor (TFT) substrate composed of glass, it is low in cost performance to incorporate the memory circuit 1000 into a TFT substrate.

Japanese Patent Application Publication No. 2004-193312 has suggested a memory cell including a data-writing line, a first voltage line, a second voltage line, an output line, a transistor having a gate to which the data-writing line is electrically connected, a first device having a variable resistance and electrically connected to the transistor, and a second device having a variable resistance and comprised of an output transistor electrically connected to a node through which the first device and the transistor are electrically connected to each other. The second device is controlled with respect to on/off thereof by an output control line.

Japanese Patent Application Publication No. 2004-30822 has suggested a memory device including a plurality of memory cells each having a first resistor having a electrically variable resistance, a second resistor having a fixed resistance, and a switching device. Each of the first and second resistors has an output terminal at one end thereof to which the switching device is electrically connected. The switching device is electrically connected to a second electrical conductor through which the output terminal is electrically connected to each of the memory cells, by virtue of signal control of a first electrical conductor arranged in each of the memory cells.

Japanese Patent Application Publication No. 2005-101535 has suggested a semiconductor device a first wiring layer, a second wiring layer different from the first wiring layer with respect to a layer, and a via-contact through which a first wiring formed on the first wiring layer is electrically connected to a second wiring formed on the second wiring layer, and which has a variable electrical conductivity. The via-contact defines a switching device having a variable electrical conductivity, and including a first terminal defined by a contact at which the via-contact makes contact with the first wiring, and a second terminal defined by a contact at which the via-contact makes contact with the second wiring. A condition with respect to electrical connection between the first and second terminals is selected from “short-circuited”, “open” and “intermediate”.

Japanese Patent Application Publication No. 2005-150243 has suggested a phase transition memory including a plurality of memory cells formed on a semiconductor substrate, each having a phase transition layer in which phase transition occurs between amorphous and crystal, a first electrode layer formed on the phase transition layer, a memory cell array comprised of the memory cells arranged in a matrix, a word line commonly electrically connected to memory cells disposed in a common row, and a bit line electrically connected to the first electrode layer, and commonly electrically connected to phase transition layers of the memory cells disposed in a common column. The phase transition layer has a first area making contact with the semiconductor substrate, and a second area through which the first areas of the memory cells disposed in a common column are electrically connected to one another. The first electrode layer is formed on the second area. An area with which the first area and the semiconductor substrate make contact in each of the memory cells is smaller than an area with which the second area and the first electrode layer make contact.

### SUMMARY OF THE INVENTION

In view of the above-mentioned problems in the conventional memory circuit, it is an object of the present invention to provide a memory circuit which is not necessary to include a sense-amplifier and a comparator, and is able to be fabricated in low cost.

In one aspect of the present invention, there is provided a memory circuit including a first resistor composed of chalcogenide, a second resistor composed of chalcogenide, and electrically connected in series to the first resistor, and an inverter having an input terminal electrically connected to a node through which the first and second resistors are electrically connected to each other.

For instance, the inverter may be comprised of a third resistor composed of chalcogenide, and a transistor having a load comprised of the third resistor.

It is preferable that the inverter is comprised of a vertically-stacked p- or n-channel CMOS inverter.

It is preferable that the chalcogenide is amorphous before data is written into the memory circuit.

The memory circuit may further include an electrically insulating substrate on which the first resistor, the second resistor and the inverter are arranged.

There is further provided a memory circuit including a power-source line, a signal line, a first thin film transistor, a first resistor composed of chalcogenide, a second resistor composed of chalcogenide, and electrically connected in series to the first resistor, an inverter having an input terminal electrically connected to a node through which the first and second resistors are electrically connected to each other, a word line, and a second thin film transistor, wherein the first thin film transistor has a gate electrically connected to the signal line, a drain electrically connected to the power-source line, and a source electrically connected to the node, the first resistor is electrically connected at one end to the power-source line and at the other end to the node, the second resistor is electrically connected at one end to the node and at the other end to a drain of the second thin film transistor, and the second thin film transistor has a gate electrically connected to the word line, a drain electrically connected to the second resistor, and a grounded source.

There is further provided a memory circuit including a power-source line, a signal line, a bit line, a first thin film transistor, a first resistor composed of chalcogenide, a second resistor composed of chalcogenide, and electrically connected in series to the first resistor, an inverter having an input terminal electrically connected to a node through which the first and second resistors are electrically connected to each other, a word line, and a second thin film transistor, wherein the first thin film transistor has a gate electrically connected to the signal line, a drain electrically connected to the power-source line, and a source electrically connected to the node, the first resistor is electrically connected at one end to the power-source line and at the other end to the node, the inverter is comprised of a third resistor composed of chalcogenide, and a third thin film transistor having a load comprised of the third resistor, the second resistor is electrically connected at one end to the node and at the other end to both a drain of the second thin film transistor and a source of the third thin film transistor, the second thin film transistor has a gate electrically connected to the word line, a drain electrically connected to both the second resistor and a source of the third thin film transistor, and a grounded source, the third resistor is electrically connected at one end to the power-source line and at the other end to a drain of the third thin film transistor, and the third thin film transistor has a gate electrically connected to the node, a drain electrically connected to both the third resistor and the bit line, and a source electrically connected to both the second resistor and a drain of the second thin film transistor.

For instance, the memory circuit in accordance with the present invention is applicable to a liquid crystal display device.

The advantages obtained by the aforementioned present invention will be described hereinbelow.

In accordance with the present invention, it is possible to fabricate a memory circuit at low cost.

That is, a level of data written into a memory circuit, which is high or low, is directly output without using a sense-amplifier and a comparator, by using a thin film transistor (TFT) fabricated on a glass or plastic substrate, for instance. Thus, it is possible to treat all of data written into a memory circuit as digital data. Accordingly, it is not necessary for a memory circuit in accordance with the present invention to include parts which operate with high accuracy, and it is now possible to comprise a memory circuit of a circuit fabricated in accordance with a process of fabricating a thin film transistor (TFT) substrate.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a circuit diagram of a conventional memory circuit.

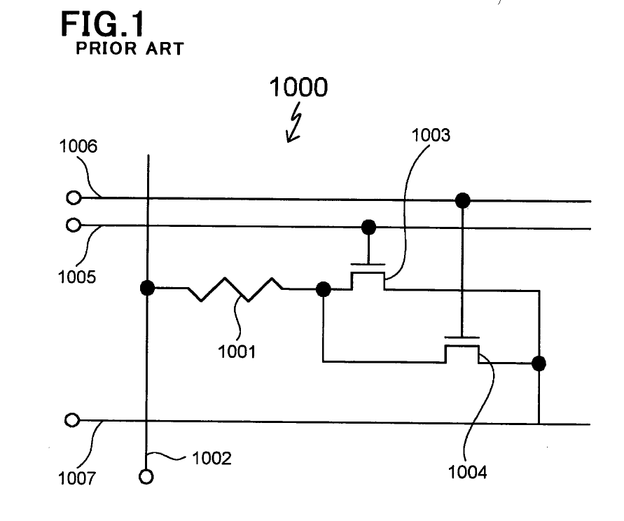

FIG. 2 is a circuit diagram of a memory circuit in accordance with the first embodiment of the present invention.

FIG. 3 is a circuit diagram of a memory circuit in accordance with the second embodiment of the present invention.

### DESCRIPTION OF THE PREFERRED EMBODIMENTS

Preferred embodiments in accordance with the present invention will be explained hereinbelow with reference to drawings.

[First Embodiment]

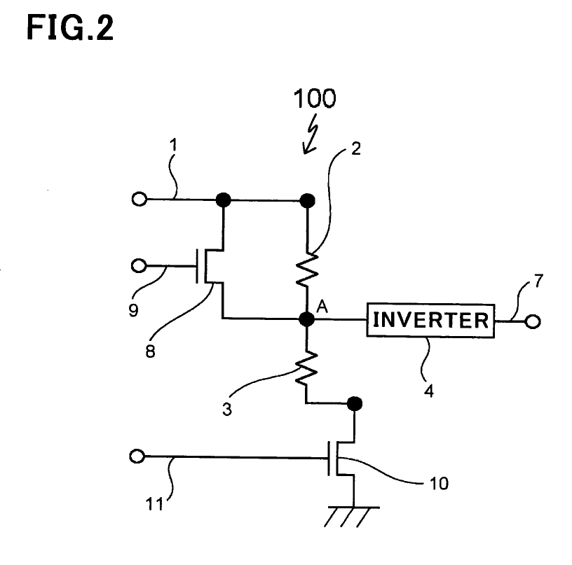

FIG. 2 is a circuit diagram of a memory circuit 100 in accordance with the first embodiment of the present invention.

The memory circuit 100 is comprised of a power-source line (Vdd) 1, a bit line 7, a signal line 9, a word line 11, a first thin film transistor 8 used for setting or resetting the memory circuit 100, a first resistor 2, a second resistor 3, an inverter 4, and a second thin film transistor 10.

A current is provided to the memory circuit 100 from a power-source (not illustrated) through the power-source line 1.

The first resistor 2 is composed of chalcogenide, and is electrically connected at one end to the power-source line 1, and at the other end to a node A.

The second resistor 3 is composed of chalcogenide, and is electrically connected in series to the first resistor 2. Specifically, the second resistor 3 is electrically connected at one end to the node A, and at the other end to a drain of the second thin film transistor 10.

The inverter 4 has an input terminal electrically connected to the node A through which the first and second resistors 2 and 3 are electrically connected in series to each other, and an output terminal electrically connected to the bit line 7.

The first thin film transistor 8 has a gate electrically connected to the signal line 9, a drain electrically connected to the power-source line 1, and a source electrically connected to the node A.

A set/reset signal is input into the gate of the first thin film transistor 8 through the signal line 9.

The second thin film transistor 10 has a gate electrically connected to the word line 11, a drain electrically connected to the second resistor 3, and a grounded source.

The second thin film transistor 10 is used for selecting the word line 11.

The first and second resistors 2 and 3 both composed of chalcogenide are initially, that is, before data is written into the memory circuit 100, in an amorphous condition, and hence, have a high resistance (about 100 mega-ohms).

Data is written into the memory circuit 100 by applying an electric signal having a low voltage in the form of a long pulse to the first and second resistors 2 and 3 to thereby turn the first and second resistors 2 and 3 into a crystal condition having a low resistance (about 100 kilo-ohms), and applying an electric signal having a high voltage in the form of a short pulse to the first and second resistors 2 and 3 to thereby turn the first and second resistors 2 and 3 back to an amorphous condition.

Hereinbelow is explained an operation of the memory circuit 100.

Since the second resistor 3 is initially in a highly-resistive condition, the node A is at a high level. Accordingly, if the word line 11 is selected, a low level signal is output through the bit line 7.

By turning on the first and second thin film transistors 8 and 10, crystallizing the second resistor 3 by the set/reset signals such that the second resistor 3 has a low resistance, and selecting the word line 11, a high level signal is output through the bit line 7, because the node A is at a low level.

The memory circuit 100 would return to an initial condition by rendering the second resistor 3 amorphous by inputting a set/reset signal into the first and second thin film transistors 8 and 10.

Hereinbelow is explained a method of fabricating the memory circuit 100.

A thin film transistor (TFT) substrate can be fabricated in accordance with the process disclosed in Japanese Patent Application Publication No. 2003-264291, for instance.

Then, a passivation film is formed with a contact hole at a region at which a contact is formed to electrically connect with a circuit having been formed in the TFT fabrication process. The contact hole is formed by conventional photoresist and etching steps.

Then, chalcogenide (compound of any one of Te, Se and S) is deposited by sputtering by the thickness of about 100 nanometers.

Then, chalcogenide is patterned by conventional photoresist and etching steps into a desired pattern.

Then, a SiNx film is formed over the patterned chalcogenide film by chemical vapor deposition (CVD) by the thickness of about 200 nanometers.

Then, the SiNx film is partially removed by conventional photoresist and etching steps to form terminals and connections. Thus, there is fabricated a thin film transistor (TFT) substrate on which the memory circuit 100 is formed.

The SiNx film has a function of preventing chalcogenide from vaporizing when chalcogenide is rendered amorphous or crystallized for rewriting data in the memory circuit 100.

In accordance with the first embodiment, since amorphous chalcogenide can have an extremely high resistance, much power is not consumed, even if the first and second resistors 2 and 3 both composed of chalcogenide are used as a converter.

Since the memory circuit 100 in accordance with the first embodiment makes use of the inverter action, it is possible to directly read a high or low data level without using a sense-amplifier and a comparator when data is to be read out of the memory circuit 100. This simplifies the memory circuit 100 in structure.

Thus, the memory circuit 100 may readily incorporated into a liquid crystal display panel, since an area of the panel would not be increased, and a fabrication yield of the panel would be reduced.

The memory circuit 100 in accordance with the first embodiment may be incorporated into a liquid crystal display (LCD) panel having a memory, or an IC tag fabricated on an electrically insulating substrate.

[Second Embodiment]

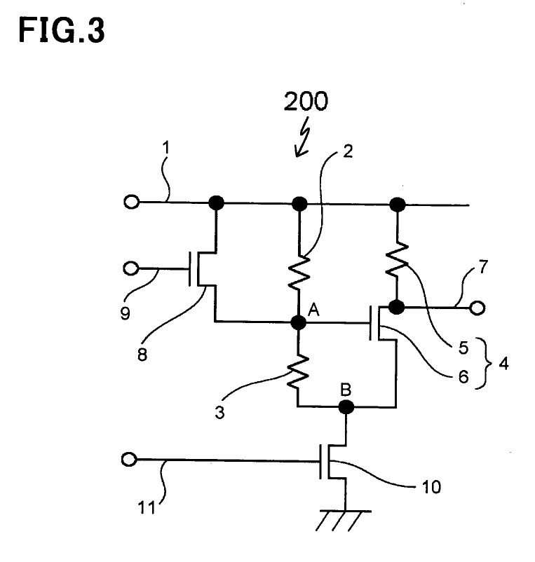

FIG. 3 is a circuit diagram of a memory circuit 200 in accordance with the second embodiment of the present invention.

The memory circuit 200 is comprised of a power-source line (Vdd) 1, a bit line 7, a signal line 9, a word line 11, a first thin film transistor 8 used for setting or resetting the memory circuit 100, a first resistor 2, a second resistor 3, an inverter 4, and a second thin film transistor 10.

The inverter 4 is comprised of a third resistor 5 composed of chalcogenide, and a third thin film transistor 6 having a load comprised of the third resistor 5.

A current is provided to the memory circuit 200 from a power-source (not illustrated) through the power-source line 1.

The first resistor 2 is composed of chalcogenide, and is electrically connected at one end to the power-source line 1, and at the other end to a node A.

The second resistor 3 is composed of chalcogenide, and is electrically connected in series to the first resistor 2. Specifically, the second resistor 3 is electrically connected at one end to the node A, and at the other end to a node B.

The first thin film transistor 8 has a gate electrically connected to the signal line 9, a drain electrically connected to the power-source line 1, and a source electrically connected to the node A.

A set/reset signal is input into the gate of the first thin film transistor 8 through the signal line 9.

The second thin film transistor 10 has a gate electrically connected to the word line 11, a drain electrically connected to the node B, and a grounded source.

The second thin film transistor 10 is used for selecting the word line 11.

The third resistor 5 is electrically connected at one end to the power-source line 1 and at the other end to both a drain of the third thin film transistor 6 and the bit line 7.

The third thin film transistor 6 has a gate electrically connected to the node A, a drain electrically connected to both the third resistor 5 and the bit line 7, and a source electrically connected to the node B.

The gate terminal of the third thin film transistor 6 defines an input terminal of the inverter 4.

The first to third resistors 2, 3 and 5 all composed of chalcogenide are initially, that is, before data is written into the memory circuit 200, in an amorphous condition, and hence, have a high resistance (about 100 mega-ohms).

Data is written into the memory circuit 200 by applying an electric signal having a low voltage in the form of a long pulse to the first to third resistors 2, 3 and 5 to thereby turn the first to third resistors 2, 3 and 5 into a crystal condition having a low resistance (about 100 kilo-ohms), and applying an electric signal having a high voltage in the form of a short pulse to the first to third resistors 2, 3 and 5 to thereby turn the first to third resistors 2, 3 and 5 back to an amorphous condition.

Hereinbelow is explained an operation of the memory circuit 200.

Since the second resistor 3 is initially in a highly-resistive condition, the node A is at a high level. Accordingly, if the word line 11 is selected, a low level signal is output through the bit line 7.

By turning on the first and second thin film transistors 8 and 10, crystallizing the second resistor 3 by the set/reset signals such that the second resistor 3 has a low resistance, and selecting the word line 11, a high level signal is output through the bit line 7, because the node A is at a low level.

The memory circuit 100 would return to an initial condition by rendering the second resistor 3 amorphous by inputting a set/reset signal into the first and second thin film transistors 8 and 10.

Hereinbelow is explained a method of fabricating the memory circuit 200.

A thin film transistor (TFT) substrate can be fabricated in accordance with the process disclosed in Japanese Patent Application Publication No. 2003-264291, for instance.

Then, a passivation film is formed with a contact hole at a region at which a contact is formed to electrically connect with a circuit having been formed in the TFT fabrication process. The contact hole is formed by conventional photoresist and etching steps.

Then, chalcogenide (compound of any one of Te, Se and S) is deposited by sputtering by the thickness of about 100 nanometers.

Then, chalcogenide is patterned by conventional photoresist and etching steps into a desired pattern.

Then, a SiNx film is formed over the patterned chalcogenide film by chemical vapor deposition (CVD) by the thickness of about 200 nanometers.

Then, the SiNx film is partially removed by conventional photoresist and etching steps to form terminals and connections. Thus, there is fabricated a thin film transistor (TFT) substrate on which the memory circuit 100 is formed.

The SiNx film has a function of preventing chalcogenide from vaporizing when chalcogenide is rendered amorphous or crystallized for rewriting data in the memory circuit 200.

In accordance with the second embodiment, since amorphous chalcogenide can have an extremely high resistance, much power is not consumed, even if the first and second resistors 2 and 3 both composed of chalcogenide are used as a converter.

Similarly, the NMOS inverter 4 comprised of the third resistor 5 and the thin film transistor 6 does not consume so much power.

Since the memory circuit 200 in accordance with the second embodiment makes use of the inverter action, it is possible to directly read a high or low data level without using a sense-amplifier and a comparator when data is to be read out of the memory circuit 200. This simplifies the memory circuit 200 in structure.

Thus, the memory circuit 200 may readily incorporated into a liquid crystal display panel, since an area of the panel would not be increased, and a fabrication yield of the panel would be reduced.

The memory circuit 200 in accordance with the second embodiment may be incorporated into a liquid crystal display (LCD) panel having a memory, or an IC tag fabricated on an electrically insulating substrate.

In the second embodiment, the NMOS inverter 4 comprised of the third resistor 5 and the n-channel thin film transistor 6 is used. In place of the n-channel thin film transistor 6, there may be used a p-channel thin film transistor which cooperates with the third resistor 5 to define a PMOS inverter 4.

As an alternative, there may be used a vertically-stacked CMOS as the inverter 4.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2005-277913 filed on Sep. 26, 2005 including specification, claims, drawings and summary is incorporated herein by reference in its entirety.

What is claimed is:

1. A memory circuit comprising:
a first resistor composed of chalcogenide;
a second resistor composed of chalcogenide, and electrically connected in series to said first resistor; and
an inverter having an input terminal electrically connected to a node through which said first and second resistors are electrically connected to each other.

2. The memory circuit as set forth in claim 1, wherein said inverter is comprised of a third resistor composed of chalcogenide, and a transistor having a load comprised of said third resistor.

3. The memory circuit as set forth in claim 1, wherein said inverter is comprised of a vertically-stacked p- or n-channel CMOS inverter.

4. The memory circuit as set forth in claim 1, wherein said chalcogenide is amorphous before data is written into said memory circuit.

5. The memory circuit as set forth in claim 1, further comprising an electrically insulating substrate on which said first resistor, said second resistor and said inverter are arranged.

6. A memory circuit comprising:
a power-source line;
a signal line;
a first thin film transistor;
a first resistor composed of chalcogenide;
a second resistor composed of chalcogenide, and electrically connected in series to said first resistor;
an inverter having an input terminal electrically connected to a node through which said first and second resistors are electrically connected to each other;
a word line; and
a second thin film transistor,
said first thin film transistor having a gate electrically connected to said signal line, a drain electrically connected to said power-source line, and a source electrically connected to said node,
said first resistor being electrically connected at one end to said power-source line and at the other end to said node,
said second resistor being electrically connected at one end to said node and at the other end to a drain of said second thin film transistor,
said second thin film transistor having a gate electrically connected to said word line, a drain electrically connected to said second resistor, and a grounded source.

7. A memory circuit comprising:
a power-source line;
a signal line;
a bit line;
a first thin film transistor;
a first resistor composed of chalcogenide;
a second resistor composed of chalcogenide, and electrically connected in series to said first resistor;
an inverter having an input terminal electrically connected to a node through which said first and second resistors are electrically connected to each other;
a word line; and
a second thin film transistor,
said first thin film transistor having a gate electrically connected to said signal line, a drain electrically connected to said power-source line, and a source electrically connected to said node,
said first resistor being electrically connected at one end to said power-source line and at the other end to said node,
said inverter being comprised of a third resistor composed of chalcogenide, and a third thin film transistor having a load comprised of said third resistor,
said second resistor being electrically connected at one end to said node and at the other end to both a drain of said second thin film transistor and a source of said third thin film transistor,
said second thin film transistor having a gate electrically connected to said word line, a drain electrically connected to both said second resistor and a source of said third thin film transistor, and a grounded source,
said third resistor being electrically connected at one end to said power-source line and at the other end to a drain of said third thin film transistor,
said third thin film transistor having a gate electrically connected to said node, a drain electrically connected to both said third resistor and said bit line, and a source electrically connected to both said second resistor and a drain of said second thin film transistor.
